(19) United States
(12) Patent Application Publication
(10) Pub. No.: US 2026/0293020 A1
(43) Pub. Date: Sep. 24, 2026

(54) VERTICAL POWER SUPPLY SYSTEM

(71) Applicant: Delta Electronics, Inc., Taoyuan City (TW)

(72) Inventors: Zhongwang Yang, Shanghai (CN); Xiaodong Chen, Shanghai (CN); Xueliang Chang, Shanghai (CN); Xiaorui Wang, Shanghai (CN)

(21) Appl. No.: 19/567,284

(22) Filed: Mar. 16, 2026

(30) Foreign Application Priority Data
Mar. 21, 2025 (CN) 202510344164.4

(51) Int. Cl. H05K 7/02

(52) U.S. Cl. CPC H05K 7/023; H05K 7/026

(57) ABSTRACT

A vertical power supply system includes a load set and a power supply set. The load set includes a first and a second load modules, the first and the second load modules respectively have a first and a second load currents, and magnitudes of the first and the second load currents are different. The power supply set includes a first and a second power supply modules, the first and the second power supply modules respectively output a first and a second supply currents, and magnitudes of the first and the second supply currents are different. The load set and the power supply set are stacked in a vertical direction, and projections, on the horizontal plane perpendicular to the vertical direction, of the first power supply module and the first load module and of the second power supply module and the second load module are respectively at least partially overlapped.

### CROSS-REFERENCE TO RELATED APPLICATIONS

This non-provisional application claims priority to China Patent Application No. 202510344164.4 filed on Mar. 21, 2025. The entire contents of the application are incorporated herein by reference for all purposes.

### FIELD OF THE INVENTION

The present disclosure relates to the field of power electronics, and more particularly to a vertical power supply system.

### BACKGROUND OF THE INVENTION

In the power supply system, the power supply layout of the variable voltage regulator (VVR) is an important part of the design of the power supply system. In the conventional VVR power supply layout, power modules of the same specification are generally used to cope with various load requirements of the chip, that is, the power modules are arranged in a decentralized manner and then electrically connected to the loads based on the power supply requirements thereof. In this design, when it is necessary to supply power to a heavy load (i.e., a load with a high current demand) in the chip, it is difficult for a single power module to independently meet the power supply requirement, and multiple power modules have to work together to supply power, which increases the transverse currents in the VVR, resulting in a large amount of heat generated in the printed circuit board (PCB), and causing the energy loss and a decrease in the overall efficiency of the power module. Moreover, the operation under high temperature for long time may reduce the service life of the power module and also reduce the reliability of the system. In addition, the transverse currents which flow horizontally in the PCB (parallel to the surface of PCB) may cause an excessive current density, which further causes a strong magnetic field and affects the stability of the power supply system.

### SUMMARY OF THE INVENTION

An object of the present disclosure is to provide a vertical power supply system for addressing the drawbacks above.

In accordance with an aspect of the present disclosure, a vertical power supply system is provided. The vertical power supply system includes a load set and a power supply set. The load set includes at least two load modules, wherein the at least two load modules include a first load module and a second load module, the first load module has a first load current, the second load module has a second load current, and magnitudes of the first load current and the second load current are different. The power supply set is configured to supply power to the load set and includes at least two power supply modules, wherein the at least two power supply modules include a first power supply module and a second power supply module, the first power supply module outputs a first supply current, the second power supply module outputs a second supply current, magnitudes of the first supply current and the second supply current are different, and wherein the first supply current is supplied to the first load module, and the second supply current is supplied to the second load module. The load set and the power supply set are stacked in a vertical direction, projections of the first power supply module and the first load module on a horizontal plane perpendicular to the vertical direction are at least partially overlapped, and projections of the second power supply module and the second load module on the horizontal plane perpendicular to the vertical direction are at least partially overlapped.

The present disclosure provides a vertical power supply system used in a power system, in which the load set requiring input current and the power supply set providing output current are stacked in a vertical direction to configure a power supply layout that the load module in the load set and the power supply module in the power supply set which have a matched current magnitude are disposed to correspond to each other. Accordingly, the load module and the power supply module having matched current magnitude can correspond to each other in the vertical direction, and thus, a single power supply module is sufficient to meet the power supply requirement of a single load module, which shortens the path for power supply, thereby significantly reducing the transverse currents in the horizontal direction (perpendicular to the vertical direction), reducing the energy loss and improving the overall efficiency. At the same time, it avoids the strong magnetic field caused by excessive current density, which affects the stability of the power system.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1A is an exploded schematic view showing a vertical power supply system according to an embodiment of the present disclosure;

FIG. 1B is an exploded schematic view showing the vertical power supply system according to the embodiment of the present disclosure from another view angle;

FIG. 2 is a schematic view showing a power supply set in the vertical power supply system according to the embodiment of the present disclosure;

FIG. 3 is a sectional view showing the vertical power supply system according to an embodiment of the present disclosure; and

FIG. 4 is a schematic view showing a power supply set in a vertical power supply system according to another embodiment of the present disclosure.

### DETAILED DESCRIPTION OF EMBODIMENTS

The present disclosure will now be described more specifically with reference to the following embodiments. It is to be noted that the following descriptions of embodiments of this disclosure are presented herein for purpose of illustration and description only. It is not intended to be exhaustive or to be limited to the precise form disclosed.

Notably, although the “first”, “second”, “third”, “fourth” and the like terms are used to describe the various elements/devices/circuits can be appreciated, these elements/devices/circuits should not be limited by these terms, and these terms are only used to distinguish one element/device/circuit from another element/device/circuit. For example, a first element could be termed a second element, and, similarly, a second element could be termed a first element, without departing from the scope of example embodiments. Also, spatially relative terms, such as “downwardly”, “upwardly”, “lower”, “upper” and the like, may be used herein for ease of description to describe one element or feature's relationship to another element(s) or feature(s) as illustrated in the figures.

Reference will be made in detail to the accompanying drawings and embodiments of the present disclosure. The embodiments are based on the technical solutions of the present disclosure, but the protection scope of the present disclosure is not limited to the following embodiments.

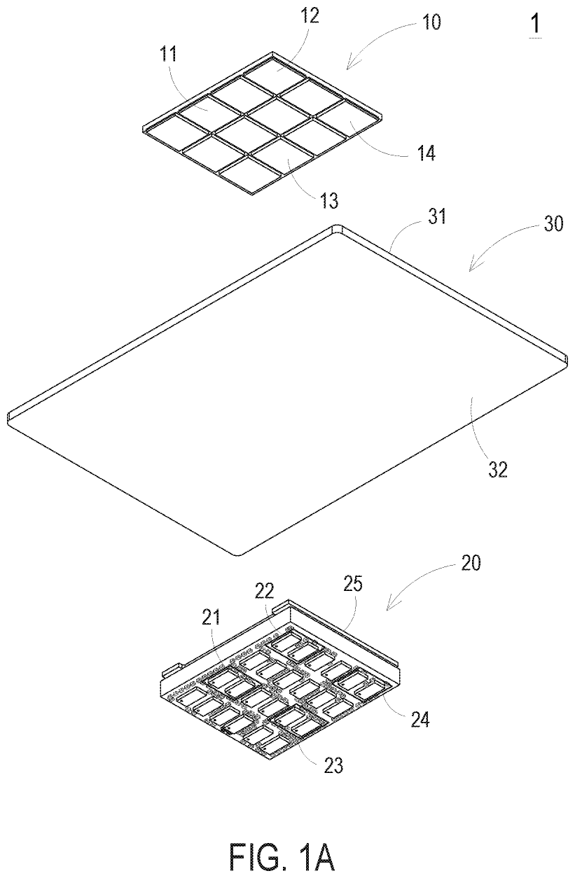

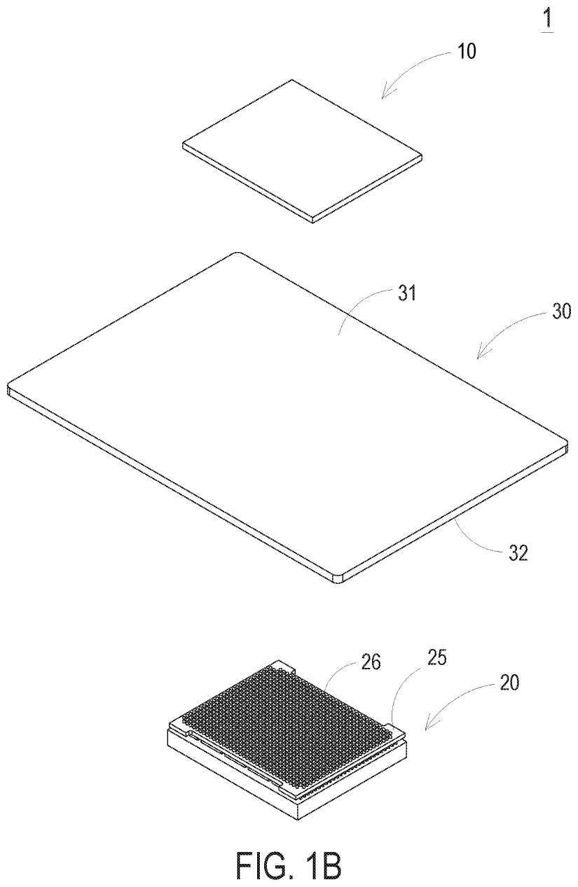

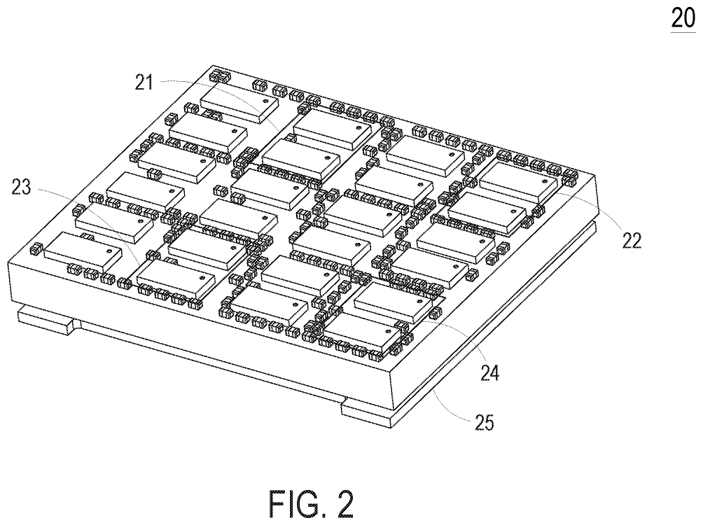

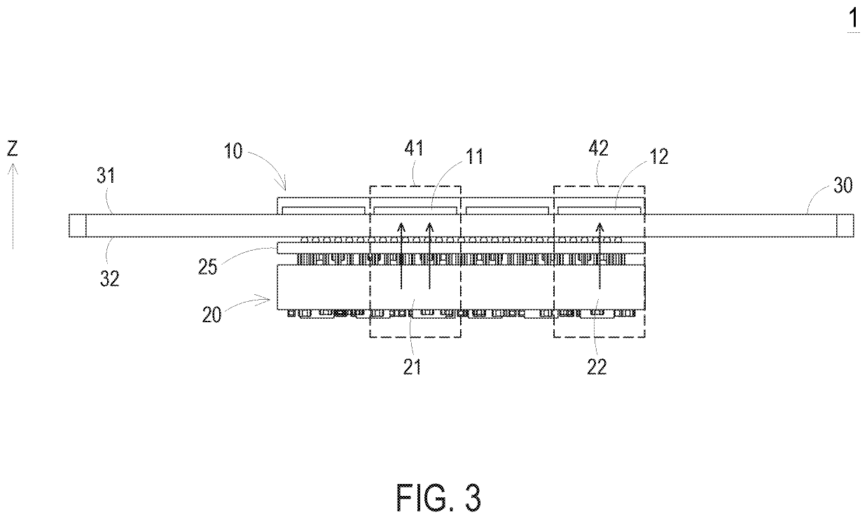

Please refer to FIG. 1A, FIG. 1B, FIG. 2 and FIG. 3. FIG. 1A and FIG. 1B are exploded schematic views showing a vertical power supply system according to an embodiment of the present disclosure from different angles, FIG. 2 is a schematic view showing a power supply set in the vertical power supply system, and FIG. 3 is a sectional view showing the vertical power supply system. A vertical power supply system 1 includes a load set 10, a power supply set 20 and a first circuit board 30. As shown in FIG. 3, in the vertical direction Z, the first circuit board 30 includes two surfaces opposite to each other, such as a first surface 31 and a second surface 32. The load set 10 and the power supply set 20 are respectively disposed on the first surface 31 and the second surface 32 of the first circuit board 30. The load set 10 and the power supply set 20 are disposed on the first circuit board 30 through welding, and electrical connection thereof is achieved through conductive vias of the first circuit board 30. For example, in an embodiment, the load set 10 can be configured as various semiconductor devices and passive components in the chip, and the power supply set 20 can be configured as a variable voltage regulator or a variable voltage regulator module for supplying power to the semiconductor devices and passive components in the chip. Further, the power supply set 20 can be configured to electrically connect to the first circuit board 30 through a second circuit board 25, for example, solder balls 26 can be disposed on a surface of the second circuit board 25 facing the first circuit board 30 for soldering the second circuit board 25 to the first circuit board 30. Notably, the vertical direction Z is the stacking direction of the load set 10, the power supply set 20 and the first circuit board 30, and the vertical direction Z is perpendicular to a plane for arranging the load set 10 and the power supply set 20, namely, perpendicular to the plane where the first circuit board 30 located.

In other embodiments, the vertical power supply system 1 also can be configured to not include the second circuit board 25, and the power supply set 20 is electrically connected to the first circuit board 30 directly.

The load set 10 and the power supply set 20 are stacked in the vertical direction Z, and positions thereof are approximately corresponding to each other. That is, on a horizontal plane perpendicular to the vertical direction Z, projections of the load set 10 and the power supply set 20 are approximately overlapped, wherein the first surface 31 and the second surface 32 of the first circuit board 30 are approximately parallel to the horizontal plane. More specifically, the load set 10 includes at least two load modules, such as a first load module 11 and a second load module 12, wherein the first load module 11 has a first load current flowing therethrough, the second load module 12 has a second load current flowing therethrough, and magnitudes of the first load current and the second load current are different, and further, each load module includes at least one load. The power supply set 20 is used to supply power to the load set 10. The power supply set 20 includes at least two power supply modules disposed on the second circuit board 25, such as a first power supply module 21 and a second power supply module 22, wherein the first power supply module 21 outputs a first supply current, the second power supply module 22 outputs a second supply current, and magnitudes of the first supply current and the second supply current are different. The first supply current flows to the first load module 11 to meet the first load current required by the first load module 11, and the second supply current flows to the second load module 12 to meet the second load current required by the second load module 12. In some embodiments, the magnitude of the first load current is equal to the magnitude of the first supply current, and the magnitude of the second load current is equal to the magnitude of the second supply current. On the horizontal plane perpendicular to the vertical direction Z, projections of the first power supply module 21 and the first load module 11 are at least partially overlapped. Notably, for minimizing the transverse current, it is preferably to overlap the projections thereof as much as possible, so that the load module and the power supply module having same current magnitude can correspond to each other in the vertical direction Z, that is, each load module has one power supply module corresponding thereto in the vertical direction Z, and each load module is supplied by said corresponding power supply module. Therefore, numbers of the load modules and the power supply modules can be identical. In some embodiments, considering factors such as practical requirements and manufacturing tolerances, the load module and the power supply module with same current magnitude do not need to completely correspond to each other in the vertical direction Z, namely, projections thereof on the horizontal plane perpendicular to the vertical direction Z are not necessarily completely overlapped, and a certain degree of deviation is allowed as long as the transverse current can be significantly reduced. Notably, in the present disclosure, the spatially relative terms are only used for describing the positional relationship and not limitations to the orientation of the system.

In the load set 10, magnitudes of the load currents of respective load modules can be identical or different. Take the chip as example, based on magnitudes of the load currents required by the semiconductor devices/passive components therein might be identical or different, magnitudes of the load currents in the load set 10 are distributed in an uneven manner. Therefore, the load modules which are divided based on positions of the semiconductor devices/passive components may have identical or different load current magnitudes depending on the semiconductor devices/passive components in the modules. In other words, the at least two load modules included in the load set 10 may have at least two kinds of load current magnitudes. Take FIG. 1A as example. The load set 10 at least includes a first load module 11, a second load module 12, a third load module 13 and a fourth load module 14, and these four load modules include at least two load current magnitudes. For example, the first load module 11 and the second load module 12 have different load current magnitudes, the third load module 13 and the second load module 12 have identical load current magnitude, and the fourth load module 14 and the first load module 11 have identical load current magnitude. The magnitudes and positions of the load currents in the load set 10 can be varied in accordance with different configurations of semiconductor devices/passive components in the chip.

Notably, although sizes of the load modules shown in the figures are the same, the sizes thereof can be varied in accordance with the practical configurations of semiconductor devices/passive components in the chip.

In the power supply set 20, magnitudes of supply currents of respective power supply modules are determined by the load modules in the vertical direction Z corresponding thereto, so that the supply current magnitudes of respective power supply modules can be identical or different. Take FIG. 2 as example, the power supply set 20 at least includes a first power supply module 21, a second power supply module 22, a third power supply module 23 and a fourth power supply module 24, wherein the first power supply module 22 approximately corresponds to the first load module 11 in the vertical direction Z, the second power supply module 22 approximately corresponds to the second load module 12 in the vertical direction Z, the third power supply module 23 approximately corresponds to the third load module 13 in the vertical direction Z, and the fourth power supply module 24 approximately corresponds to the fourth load module 14 in the vertical direction Z. That is, on the horizontal plane perpendicular to the vertical direction Z, projections of each power supply module and the corresponding load module are at least partially overlapped. Moreover, the first power supply module 21 provides a corresponding first load current to the first load module 11, the second power supply module 22 provides a corresponding second load current to the second load module 12, the third power supply module 23 provides a corresponding third load current to the third load module 13, and the fourth power supply module 24 provides a corresponding fourth load current to the fourth load module 14. Accordingly, because the first load module 11 and the second load module 12 have different load current magnitudes, the supply current magnitudes of the first power supply module 21 and the second power supply module 22 are different; and because the third load module 13 and the second load module 12 have the same load current magnitude and the fourth load module 14 and the first load module 11 have the same load current magnitude, the supply current magnitudes of the third power supply module 23 and the second power supply module 22 are the same and the supply current magnitudes of the fourth power supply module 24 and the first power supply module 21 are the same. Therefore, the at least two power supply modules included in the power supply set 20 may have at least two kinds of supply current magnitudes for respectively supplying power to the load set 10 to meet the at least two kinds of load current magnitudes, and further, through the configuration that corresponding power supply module and load module are arranged in the vertical direction Z, the current path between the load set 20 and the load set 10 can be shortened.

Moreover, each power supply module includes one or more power semiconductor devices, and each power semiconductor device is a basic power unit for realizing input-output voltage conversion; and the power supply modules having different supply current magnitudes respectively employ power semiconductor devices with different power levels.

Notably, although sizes of the power supply modules shown in the figures are the same, the sizes thereof can be identical or different, for example, can be varied in accordance with the sizes of the corresponding load modules.

Through the configuration described above, no matter what the required magnitude of the load current of each semiconductor device/passive element in the chip is, a current having corresponding magnitude can be provided by the corresponding power supply module located in the vertical direction Z. That is, a light load module (with small load current demand) is powered by a power supply module with low power level correspondingly arranged in the vertical direction Z, and a heavy load module (with large load current demand) is powered by a power supply module with high power level correspondingly arranged in the vertical direction Z. For example, as shown in FIG. 3, the load set 10 and the power supply set 20 form at least two vertical power supply sections. The at least two vertical power supply sections include a first vertical power supply section 41 and a second vertical power supply section 42. The first vertical power supply section 41 includes the first load module 11 and the first power supply module 21 which are corresponding to each other in the vertical direction Z and are electrically connected through the first circuit board 30. The second vertical power supply section 42 includes the second load module 12 and the second power supply module 22 which are corresponding to each other in the vertical direction Z and are electrically connected through the first circuit board 30. Here, if the first load module 11 is the heavy load module, the second load module 12 is the light load module, and accordingly, the magnitude of the first supply current of the first power supply module 21 is greater than the magnitude of the second supply current of the second power supply module 22, and magnitudes of respective supply currents correspond to respective magnitudes of the load currents of respective load modules.

Accordingly, compared with the prior art where the heavy load module has to be supplied by multiple power supply modules, the configuration in the present disclosure which arranges the power supply module having a supply current magnitude equal to a required load current magnitude of the load module in the vertical direction Z can significantly reduce the transverse currents transmitted in the horizontal direction in the power supply set 20, thereby effectively avoiding the energy loss caused by the large amount of transverse currents, reducing the heats generated in the power module, and thus improving the overall efficiency. At the same time, it avoids the strong magnetic field caused by excessive current density, which affects the stability of the power system.

More specifically, the present disclosure modularizes the load modules to have different load currents, and the power supply modules having respectively corresponding supply currents are arranged in the vertical direction Z, so that not only the physical positions are vertically corresponding to each other, the magnitudes of the load current and the power supply current are also mutually met. Therefore, in addition to minimizing the current paths between the load modules and the power supply modules which are physically corresponding to each other, it is also possible to achieve that a single power supply module is sufficient to meet the power supply requirement of the heavy load module, thereby solving various problems in the prior art caused by the need for multiple power supply modules to supply power to a single heavy load module.

In the present disclosure, the power supply set 20 can be configured as a single power module. For example, as shown in FIG. 2, the power supply modules 21, 22, 23, 24 can be power units in one single power module having different supply current densities, so as to supply currents with different magnitudes in accordance with different load requirements of corresponding load modules in the vertical direction Z. Here, the current density refers to the amount of current flowing per unit area.

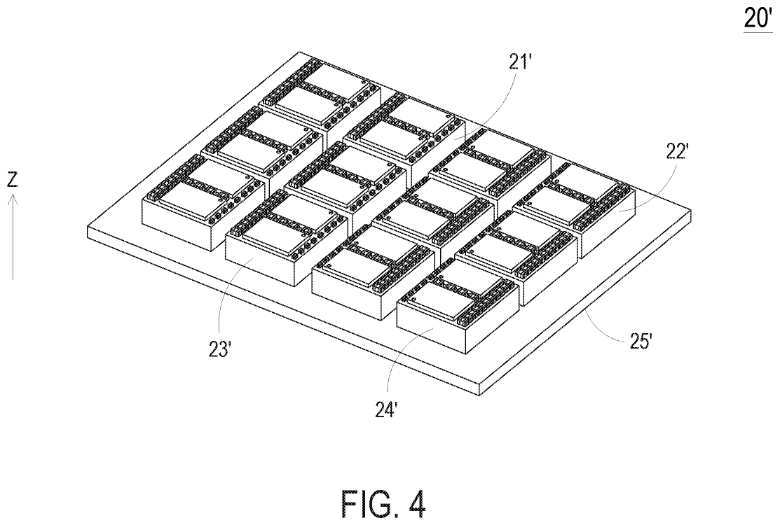

The power supply set 20 also can be configured as other types. Please refer to FIG. 4 which is a schematic view showing the power supply set in the vertical power supply system according to another embodiment. In this embodiment, a power supply set 20′ includes at least two power modules which are respectively independent and disposed on the circuit board 25′ in a close arrangement manner. That is, the first power supply module 21′, the second power supply module 22′, the third power supply module 23′ and the second power supply module 24′ can supply power independently. For example, each power supply module can be configured as one power module, and respective power supply modules can be collectively disposed on one circuit board for corresponding to multiple load modules based on the requirement of the load modules, so as to form the power supply set 20′. Under this configuration, identically, each power supply module corresponds to and supplies a current with corresponding magnitude to the corresponding load module in the vertical direction Z.

In practice, the heavy load module has a greater current density, and the light load module has a smaller current density. Here, the current density refers to a ratio of a working current divided by a vertical cross-sectional area of the current path. Therefore, in the identical vertical cross-sectional area, the larger the current of the load requirement means the greater the current density.

In an embodiment, a ratio of the current density of the power supply module to the current density of the load module corresponding thereto in the vertical direction Z is greater than or equal to 70%. In some embodiments, the ratio can be less than or equal to 130%, namely, the current density of the power supply module can be 0.7 to 1.3 times the current density of the load module corresponding thereto, and accordingly, single power supply module is sufficient to provide the current required by the corresponding load module. For example, take FIG. 3 as example, the current density of the first power supply module 21 in the first vertical power supply section 41 is greater than or equal to 70% of the current density of the first load module 11, and less than or equal to 130% of the current density of the first load module 11; and the current density of the second power supply module 22 in the second vertical power supply section 42 is greater than or equal to 70% of the current density of the second load module 12, and less than or equal to 130% of the current density of the second load module 12.

In some embodiments, a difference of current densities between the power supply modules respectively in different vertical power supply sections can be larger than 150%. For example, take FIG. 3 as example, if the first load module 11 in the first vertical power supply section 41 is a heavy load module and the second load module 12 in the second vertical power supply section 42 is a light load module, the current density provided by the first power supply module 21 in the first vertical power supply section 41 is at least 150% of the current density provided by the second power supply module 22 in the second vertical power supply section 42, namely, the current density provided by the first power supply module 21 in the first vertical power supply section 41 is at least 1.5 times the current density provided by the second power supply module 22 in the second vertical power supply section 42. Moreover, the power supply modules having different supply current magnitudes employ respective power semiconductor devices which have a difference of rated currents larger than 150%. Namely, the magnitude of the rated current of the power semiconductor device used in the first power supply module 21 of the first vertical power supply section 41 is 1.5 times the magnitude of the rated current of the power semiconductor device used in the second power supply module 22 of the second vertical power supply section 42. Different from the prior art which simply increases the number of identical power semiconductor devices to meet the increased requirement of the load module, in the present disclosure, for the load modules having different power supplying requirements, power semiconductor devices with corresponding power levels are provided in the vertical direction Z, thereby not only minimizing the whole volume of the vertical power supply system, but also reducing the line loss and heat loss.

In conclusion, in the vertical power supply system of the present disclosure, through dividing the load set into the load modules based on the respective load current magnitudes thereof and arranging the power supply modules having respectively corresponding output current magnitudes in the vertical direction to correspond to the load modules, the transverse currents in the horizontal direction during power supplying can be significantly reduced, thereby effectively avoiding energy loss caused by large amount of transverse currents in the horizontal direction, increasing current density and improving power supply efficiency. At the same time, it avoids the strong magnetic field caused by excessive current density, which affects the stability of the power system.

While the disclosure has been described in terms of what is presently considered to be the most practical embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A vertical power supply system, comprising:
a load set comprising at least two load modules, wherein the at least two load modules comprise a first load module and a second load module, the first load module has a first load current, the second load module has a second load current, and magnitudes of the first load current and the second load current are different; and
a power supply set configured to supply power to the load set and comprising at least two power supply modules, wherein the at least two power supply modules comprise a first power supply module and a second power supply module, the first power supply module outputs a first supply current, the second power supply module outputs a second supply current, magnitudes of the first supply current and the second supply current are different, and wherein the first supply current is supplied to the first load module, and the second supply current is supplied to the second load module,
wherein the load set and the power supply set are stacked in a vertical direction, projections of the first power supply module and the first load module on a horizontal plane perpendicular to the vertical direction are at least partially overlapped, and projections of the second power supply module and the second load module on the horizontal plane perpendicular to the vertical direction are at least partially overlapped.

2. The vertical power supply system as claimed in claim 1, wherein the load set and the power supply set form at least two vertical power supply sections, and the at least two vertical power supply sections comprise a first vertical power supply section and a second vertical power supply section, wherein the first vertical power supply section comprises the first power supply module and the first load module and the first supply current is supplied to the first load module along the vertical direction, and the second vertical power supply section comprises the second power supply module and the second load module and the second supply current is supplied to the second load module along the vertical direction.

3. The vertical power supply system as claimed in claim 2, wherein in each of the at least two vertical power supply sections, a ratio of a current density of a corresponding one of the at least two power supply modules to a current density of a corresponding one of the at least two load modules is greater than or equal to 70%.

4. The vertical power supply system as claimed in claim 3, wherein in each of the at least two vertical power supply sections, a ratio of the current density of the corresponding one of the at least two power supply modules to the current density of the corresponding one of the at least two load modules is less than or equal to 130%.

5. The vertical power supply system as claimed in claim 1, further comprising a first circuit board having two opposite surfaces in the vertical direction, wherein the two opposite surfaces of the first circuit board are parallel to the horizontal plane, the load set and the power supply set are respectively arranged on the two opposite surfaces, and the load set and the power supply set are electrically connected via the first circuit board.

6. The vertical power supply system as claimed in claim 5, further comprising a second circuit board disposed between the power supply set and the first circuit board, wherein the power supply set is electrically connected to the first circuit board via the second circuit board.

7. The vertical power supply system as claimed in claim 1, wherein each of the at least two power supply modules is an independent power module.

8. The vertical power supply system as claimed in claim 1, wherein the power supply set is a single power module, and each of the at least two power supply modules is a different power unit in the single power module.

9. The vertical power supply system as claimed in claim 1, wherein each of the at least two power supply modules comprises at least one power semiconductor device, and the at least two power supply modules having different supply current magnitudes comprise power semiconductor devices with different power levels.

10. The vertical power supply system as claimed in claim 9, wherein respective power semiconductor devices in two of the at least two power supply modules having different supply current magnitudes have different rated currents, and one of the rated currents is at least 1.5 times the other of the rated currents.

11. The vertical power supply system as claimed in claim 1, wherein two of the at least two power supply modules having different supply current magnitudes have different current densities, and one of the current densities is at least 1.5 times the other of the current densities.

12. The vertical power supply system as claimed in claim 1, wherein the load set is configured as a chip and the power supply set is configured as a variable voltage regulator.
